(19) United States
(12) Patent Application Publication
(10) Pub. No.: US 2011/0114155 A1
(43) Pub. Date: May 19, 2011

(54) SOLAR ENERGY USE

(75) Inventor: Alexander Stoev, Forch (CH)

(73) Assignee: IDS HOLDING AG, Zug (CH)

(21) Appl. No.: 12/997,125

(22) PCT Filed: Jun. 9, 2009
(86) PCT No.: PCT/CH2009/000188

§ 371 Date: Jan. 20, 2011

(30) Foreign Application Priority Data
Jun. 10, 2008 (CH) 878/08
Jun. 8, 2009 (CH) 876/09

(51) Int. Cl. H01L 31/052; B21D 53/02; H01L 31/058

(52) U.S. Cl. 136/246; 29/890.038

(57) ABSTRACT

The solar combination panel, including a solar panel and a heat exchanger, has a tubular heat exchanger at the back of a solar panel, by which the solar panel can always be operated in the optimal temperature range so as to improve the electricity yield. A host of heat collector sheets, which are provided as heat collectors and are attached by cementing, are located on the back cover film of the solar panel. Fluted metal adhesive plates are located on the heat collector sheets. The fluted metal adhesive plates are likewise cemented and in the fluting of which a metal pipe is geometrically cemented such that in this way the transmission of power from the heat exchanger to the solar panel is minimized. A method for producing the solar combination panel is described.

The invention relates to an embodiment for a solar combination panel with which, on the one hand, the recovery of electrical energy is maximized and at the same time a major portion of the energy that is incident on the module is thermally used according to claim 1, and a method for this purpose according to claim 16.

Solar energy today is used technically mainly in two ways, specifically thermally or electrically.

In the simplest case, thermal use consists in that the solar radiation that is incident on a dark body heats the latter and this heat energy is routed to a thermal consumer by means of a heat transport medium. Thus, with simple means at a radiation intensity of 1 kW/m², roughly 40%—with expensive solar collectors up to 80%—of this energy can be used.

In electrical use, the object is to convert as high a proportion of all of the solar radiation as possible into electrical current. This takes place by the use of solar cells. Current large-area solar cells of silicon, assembled into so-called solar panels, can convert roughly 5% to roughly 20% of all of the radiation into direct current, therefore roughly 50 W/m² to 200 W/m², depending on the design. The remaining 95% to 80% of all of the radiation heats the panel and the solar cells contained in it in an unwanted manner and thus reduces their efficiency by up to roughly 0.5%/° C. The energy that has not been used electrically is absorbed by the environment and therefore cannot be further used.

If both types of energy are to be used, electrical solar panels and thermal collectors are generally located next to one another and are used separately.

In recent years, individual companies have attempted to combine the panels into combination panels, also called PVT panels (Photo Voltaic Thermal Panels). In a shared, generally specially insulated housing of typically roughly 1 m² surface area, there are both a solar cell arrangement corresponding to a conventional panel and also an air or water heat exchanger, by which installation area and accordingly also mounting hardware are reduced.

For this purpose, special panel housings are built that are rather heavy, voluminous and expensive, for which reason this technology has been little used.

The object of the invention is to propose a new design that is based on standard modules and is achieved with the following:

Use of commercial modules of various module manufacturers, the solar cells with infrastructure usually being mounted on a glass plate as a carrier,

A reduction of the specific weight and of the volume of the thermal part of the module,

Low production costs by using standard materials for the required heat exchangers,

Free choice of the coolant, especially the possibility of service water cooling (or heating),

Cool operation of the module for increasing the solar conversion efficiency,

Operation in the heating mode to melt snow and ice coatings for increasing the current yield.

The object is achieved by a solar combination panel with which, on the one hand, the recovery of electrical energy is maximized and at the same time a major portion of the energy that is incident on the module is thermally used.

Here, the focus is not primarily on the thermal efficiency; the emphasis is on improving the electrical efficiency or current yield, for example by de-icing the panel surface and thus enabling longer exposure to solar radiation. Due to the relatively poor electrical efficiency of the panel, generally a very large area for thermal use is available anyway.

The invention is explained in more detail below using the figures. Here:

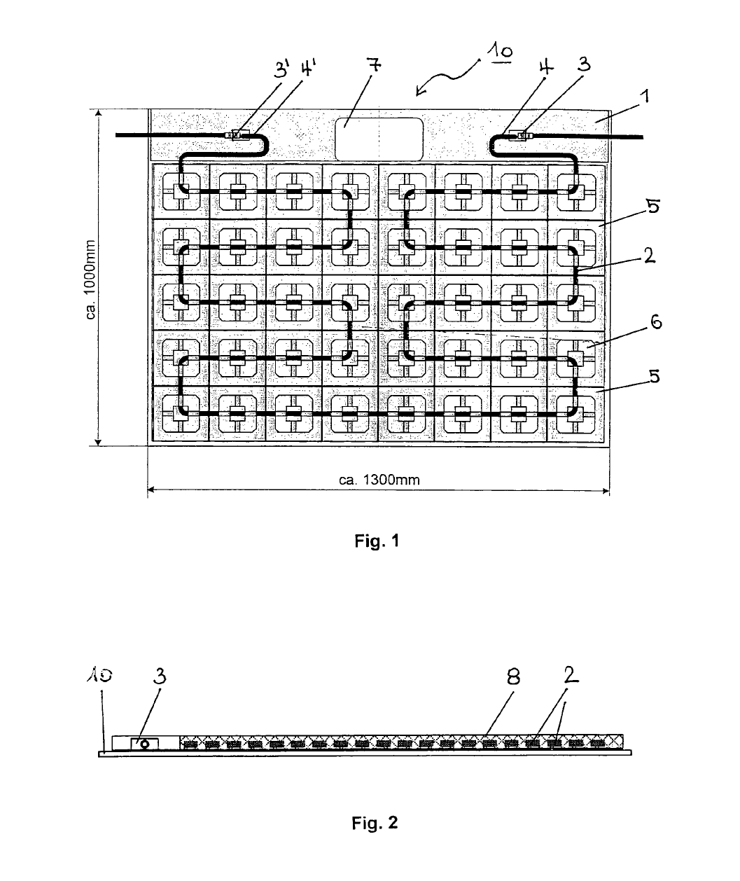

FIG. 1 shows a rear view of a frameless solar combination panel with heat exchanger and insulation

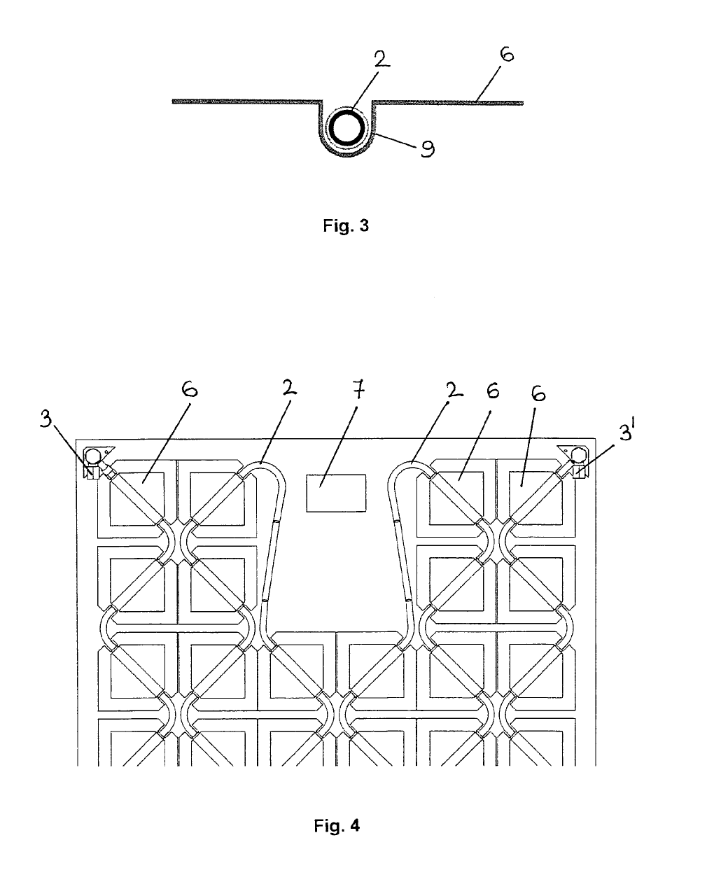

FIG. 2 shows a side view to FIG. 1

FIG. 3 shows an aluminum adhesive plate with the thermally-bonded pipe in a cross-section

FIG. 4 shows an extract of the rear view of a solar combination panel with metal pipes arranged in a zigzag

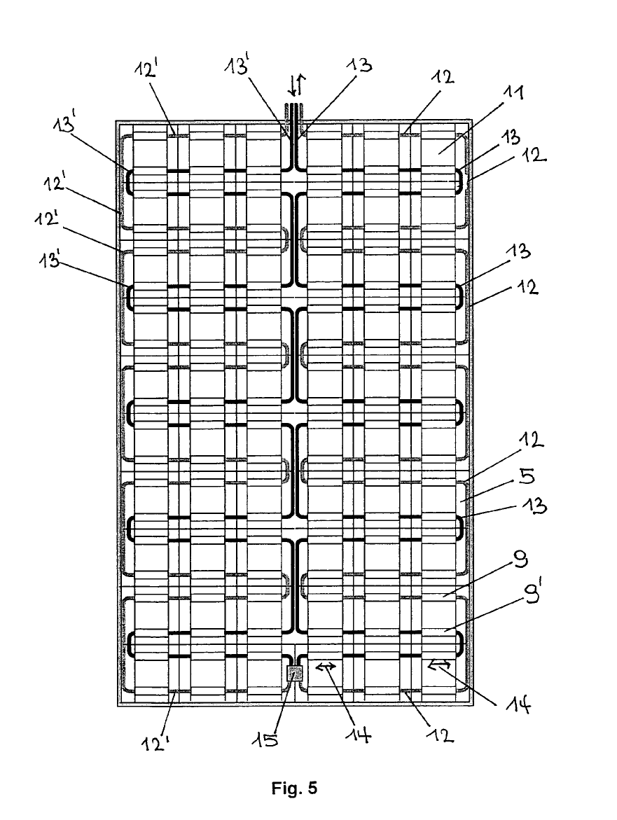

FIG. 5 shows a rear view of a solar combination panel as a second embodiment.

The construction principle is shown using a frameless solar panel according to FIG. 1, this figure being used at the same time as a first embodiment.

A frameless solar panel 10 with dimensions of roughly 1 m×1.3 m has a standard execution as a large tile for roof integration.

There is a strip-shaped overlapping region 1 (=shading region) for the resting tile.

On the back of the solar panel, a metal pipe 2, preferably an aluminum pipe, is attached in a meander fashion, and a cooling liquid, preferably water, flows through it, and the pipe forms the heat exchanger.

In the overlapping region, connections 3, 3′ are attached on the pipe ends 4, 4′ via which connections the solar panel is connected to a cooling circuit. In the overlapping region 1, there is furthermore an electrical terminal box 7.

Outside of the overlapping region 1, the solar panel has approximately square or rectangular aluminum heat distributor sheets, or heat collector sheets 5, which almost blanket the entire remaining panel surface that is to be cooled.

On the heat collector sheets 5, there are aluminum adhesive plates 6 into which the aluminum pipes 2 are cemented. The aluminum adhesive plates 6 are used for thermal bonding of the aluminum pipes 2 to the heat collector sheets 5 and are described in more detail later.

FIG. 2 shows a side view to FIG. 1. The frameless solar panel 10, the connection 3 in the overlapping region, and the aluminum pipes 2 are visible. Optionally, thermal back insulation 8 with which excess heat loss is prevented is mounted over the aluminum adhesive plates. Another metal with good heat conduction can be used in place of aluminum for the pipes. In addition to aluminum, the use of copper, iron, steel and their alloys is conceivable. In addition to thermal conductivity, the ductility, strength and processability play an important role.

FIG. 3 shows the aluminum adhesive plate with the heat-bonded pipe 2 in a cross-section. The aluminum adhesive plate 6 has a thickness of 0.5-2 mm and has fluting 9 in the middle.

FIG. 4 shows a cutaway of the rear view of a solar combination panel with metal pipes arranged in a zigzag. The metal pipes 2, the connections 3, 3′, the electrical terminal boxes 7 and the aluminum adhesive plates 6 are visible. On the aluminum adhesive plates 6, the metal pipes are diagonally mounted, a zigzag arrangement of the metal pipes being produced with pipe bends of roughly 90°.

The production of the heat exchanger is described below.

The standard structure of a solar module generally consists of a glass plate a few mm thick that is used as a mechanical carrier of the solar cells. The latter are embedded in a molten film together with the electrical connections between the cells. The back layer (cover layer) of the module generally consists of a durable plastic film that is likewise securely connected to the module sandwich.

The cover layer is first of all cemented to a number of thin aluminum plates that act as heat collector sheets 5 and absorb most of the heat that accumulates on the cells. To keep the thermal expansion stresses low, the plates are applied to the cover layer with a small lateral distance of roughly 1% of the side dimensions of the plates. For this purpose, a permanent elastic cement that adheres well is used in a small layer thickness of roughly 0.1 to 0.3 mm. It is advantageous to match the individual plate size roughly to the dimensions of the solar cells used in the module. The cement used has a thermal conductivity of 0.7-2.0, preferably 1.0 W/mK.

The heat that has been collected in the heat collector sheets 5 must now be transmitted to the cooling pipe or the aluminum pipe 2. So that the drop in temperature remains low, a fluted aluminum adhesive plate 6 with a thickness of 0.5 to 2 mm is used and connected to the cooling pipe by way of heat-conducting cement. The aluminum adhesive plate 6 for its part is likewise connected semiflexibly to the heat collector sheets 5 by way of a cement layer that is as thin as possible. Thus, on the one hand, a relatively good thermal connection from the module to the cooling water is formed, and, on the other hand, the cooling pipe is reliably attached.

In the described case, the water connection sites 4, 4′ are located to the left and right next to the electrical terminal box 7.

To prevent excess heat loss via the back layers, the latter including the cooling pipe arrangement can be terminated with a heat-insulating molded part or back insulation 8.

When the aluminum pipe 2 and the aluminum adhesive plate 6 are connected to the module or its back layer, the thermal expansions of the materials involved must be considered. Here, the most urgent measure is to achieve a certain mechanical decoupling of the heat exchanger structure from the base module. In order to keep the expansion forces small, the cooling pipe meander must be divided as much as possible into partial lengths that from one pipe bend to the next pipe bend are generally smaller than half the narrow side of the module long. Furthermore, all cementing is done by means of permanent elastic cement so that the construction allows a few tenths of a mm expansion without unallowable bending forces being applied to the solar module.

Tests have shown that this requirement can be satisfied by suitable selection of the geometry of the cooling pipe meander, the cement elasticity, and the choice of the cement gap thicknesses.

A reduction of the mechanical stress and an increase of the allowable temperature differences between the cooling water and carrier glass of the solar module can be advantageously achieved by diagonal routing of the cooling pipe, as shown in FIG. 4. Heat-carrying cementing of the aluminum plates is done analogously as is described above.

Furthermore, it is possible to make the cement gaps between the adhesive plate and the cooling pipe movable, alternatively or in addition to preventing complicated pipe routing, by the pipe being treated before cementing with a very thin silicone layer, for example a thermally conductive grease. In this way, solid cementing is prevented, so that a type of sliding seat is formed, by which the pipe can move, for example, in the fluting of the adhesive plate at the thermal-mechanical boundary stress that occasionally occurs. In this way, thermal contact is maintained.

For larger exemplary solar combination panels as described above, the cooling arrangement can be advantageously divided into surface parts, one of these surface parts corresponding at most to the masses of the above-described embodiment.

One especially advantageous embodiment of the solar combination panel uses fluted metal heat collector sheets, with which the use of metal adhesive plates can be eliminated.

Operation of the module.

It is intended that the thermal part of the module be cooled by circulating water that preferably has a rather low temperature of roughly 25 to 30° C. In this way, on the one hand—as further mentioned above—the electrical conversion efficiency is kept at a high value, and, on the other hand, the differences in the thermal expansions are minimized, and thus it is also unnecessary to have to resort to expensive plastics or cements for elevated temperature ranges.

If the module is operated at normal temperature for the aforementioned reasons, thermal use takes place preferably via heat pumps.

In summer operation, it is furthermore feasible to dissipate the excess heat into the ground by means of earth probes or earth registers or—if present—into a water reservoir (for example, a lake) or also via a water-air heat exchanger into the ambient air, and these methods can be combined in any way desired, depending on where they are used.

In winter operation, with the corresponding design of the probes or heat exchangers, heat can be briefly applied for the purpose of thawing the solar modules.

Preferably, winter operation takes place roughly at 50° in order to use as much heat as possible and to require little power for the heat pump or to be able to omit the pump entirely.

Preferably, summer operation takes place roughly at 25° in order to keep the electrical efficiency as high as possible.

FIG. 5 shows the rear view of a solar combination panel as a second embodiment. The solar panel here consists of 6×10 square cells 11 of 150 mm×150 mm. On the back of the module in the cell region, the aluminum heat collector sheets with 150 mm×150 mm and a thickness of 1.0 mm are cemented. The heat exchanger is designed as an aluminum pipe with an 8 mm diameter in double routing, the aluminum pipe being routed in each case twice over the aluminum heat collector sheets. A first aluminum pipe 12, 12′ that is routed in a meander alternates with a second aluminum pipe 13, 13′ that is routed in a meander so that both the first aluminum pipe 12 and also the second aluminum pipe 13 are routed over each aluminum heat collector sheet 5. The first and second aluminum pipes are connected to a connector 15. This double routing of the aluminum pipes over the aluminum heat collector sheets minimizes the heat conduction distance; this has proven especially advantageous. The aluminum pipes that have been introduced into the fluting 9, 9′ thus have a sliding seat; this is indicated with the arrows 14. This sliding seat thus contributes significantly to accommodating the expansion problems in the transverse direction of the solar combination panel. In the lengthwise direction of the solar combination panel, the expansion is accommodated by the many rectangular bends in the aluminum pipes. In the lengthwise direction, the heat exchanger acts like a spring. The heat exchanger is surrounded by a hard foam casting (not shown) or lies embedded in the latter. The hard foam casting forms here the carrier for the heat exchanger and is typically 20 mm thick.

In this embodiment, dividing or segmenting the solar module has proven especially advantageous by using commercially available photovoltaic modules (PVM) (for example, IDS Solar AG, Sofia, Bulgaria). With this dividing, on the one hand, and the configuration of the heat exchanger, on the other hand, the problems of thermal expansion can be managed. This results in a minimization of power transmission from the heat exchanger to the solar panel or to the photovoltaic modules. Using aluminum yields a lightweight construction for a solar combination panel at low production costs.

Such solar combination panels with the electrical part are used in grid feed and isolated operation (for example, 24 V), with the thermal part in industrial facilities as process heat, such as, for example, in grass drying and in drying installations.

1. Solar combination panel, comprising a solar panel and a heat exchanger, wherein on the back of a solar panel, there is a tubular heat exchanger, by which the solar panel can always be operated in the optimum temperature range to improve the current yield, wherein the solar panel on its back cover film has a host of heat distributor sheets or heat collector sheets that are intended as heat collectors and are attached on the back cover film by being cemented, wherein at least one of:
a) the heat collector sheets have at least one fluting, and
b) metal adhesive plates are cemented on the heat collector sheets, and said plates have at least one fluting, and
in the fluting of which a metal pipe is cemented that forms the cooling or heating circuit of the heat exchanger and in that in this way, the transmission of power from the heat exchanger to the solar panel can be minimized.

2. Solar combination panel according to claim 1, wherein the metal pipe, the heat collector sheets, and the metal adhesive plates are comprised of a material selected from the group consisting of aluminum, copper, iron, steel and alloy thereof.

3. Solar combination panel according to claim 1, wherein the metal pipe is attached in a meander or zigzag.

4. Solar combination panel according to claim 1, wherein the metal adhesive plates have a thickness of 0.5-2.0 mm.

5. Solar combination panel according to claim 1, wherein in the region of the fluting, the thermal connection between the metal adhesive plates and the metal pipes takes place with a cement with good thermal conductivity.

6. Solar combination panel according to claim 5, wherein the cement has a thermal conductivity of 0.7-2.0, W/mK.

7. Solar combination panel according to claim 1, wherein the heat collector sheets with the metal adhesive plates have thin-layer, semiflexible cementing of 0.1-1.0 mm.

8. Solar combination panel according to claim 1, comprising heat-insulating back insulation to prevent excess heat loss via the back layers including the heating/cooling pipe arrangement.

9. Solar combination panel according to claim 1, wherein the metal pipe is present routed twice in the heat collector sheets, by which the heat conduction distance is minimized.

10. Solar combination panel according to claim 1, wherein the metal pipe includes a first aluminum pipe that is routed in a meander and a second aluminum pipe that is arranged in alternation and that is routed in a meander, both the first aluminum pipe and the second aluminum pipe being routed over each heat collector sheet.

11. Solar combination panel according to claim 8, wherein the back insulation is comprised of a hard foam casting that is made as a carrier for the heat exchanger.

12. Solar combination panel according to claim 1, wherein the metal pipe is movably held in the channel of the fluted metal adhesive plate for equalizing thermal expansions of a few tenths of a mm.

13. Solar combination panel according to claim 1, wherein the solar panel is present in segmented form and consists of a host of photovoltaic modules (PVM).

14. A method of operating a solar combination panel according to claim 1 for grid feed and isolated operation.

15. A method of operating a solar combination panel according to claim 1 in industrial installations.

16. Method for producing a solar combination panel according to claim 1, wherein the back cover film of the solar panel is cemented to heat collector sheets, wherein the metal pipes are inserted in fluted metal adhesive plates and are cemented to the latter, and wherein the metal pipes with the fluted metal adhesive plates are placed on the heat collector sheets and cemented.

17. Method for producing the solar combination panel according to claim 16, wherein a hard foam casting is used as a back insulation.

18. Solar combination panel according to claim 5, wherein the cement has a thermal conductivity of 1.0 W/mk.

19. Method according to claim 15, wherein the industrial installations include at least one of grass drying and drying installations.
